(19) United States
(12) Patent Application Publication
(10) Pub. No.: US 2016/0262271 A1
(43) Pub. Date: Sep. 8, 2016

(54) METHOD FOR MANUFACTURING A DOUBLE-SIDED PRINTED CIRCUIT BOARD

(71) Applicant: OBSCHCHESTVO S OGRANICHENNOY OTVETSTVENNOSTYU "KOMPANIYA RMT", Nizhny Novgorod (RU)

(72) Inventors: Aleksandr Aleksandrovich NAZARENKO, Moscow (RU); Evgeny Aleksandrovich NOVIKOV, Moskovskaya obl. (RU); Aleksandr Mikhailovich LIPKIN, Vladimirskaya obl. (RU); Gennady Gyusamovich GROMOV, Moscow (RU); Vasily Vasilyevich VOLODIN, Moscow (RU)

(73) Assignee: OBSCHCHESTVO S OGRANICHENNOY OTVETSTVENNOSTYU "KOMPANIYA RMT", Nizhny Novgorod (RU)

(21) Appl. No.: 15/026,912

(22) PCT Filed: Aug. 12, 2014
(86) PCT No.: PCT/RU14/00604

§ 371 Date: Apr. 1, 2016

(30) Foreign Application Priority Data
Oct. 3, 2013 (RU) 2013144431

(51) Int. Cl. H05K 3/40; H05K 3/06; H05K 3/28; H05K 3/38; H05K 3/14; H05K 3/22; H05K 1/03; H05K 3/00; H05K 1/09

(52) U.S. Cl. CPC H05K 3/4076; H05K 3/0029; H05K 3/062; H05K 3/28; H05K 1/09; H05K 3/146; H05K 3/22; H05K 1/0306; H05K 3/388; H05K 2203/107

(57) ABSTRACT

The method for manufacturing printed circuit boards includes providing through hole vias in a non-conductive substrate at given coordinates in a printed circuit board topology, then an adhesive undercoat, a conductive layer and a metal mask layer are applied, in a single process, to the surface of the substrate and to the walls of the vias. A soluble protective layer is applied to the mask layer and to the walls of the vias, then a circuit board pattern is formed by laser evaporation, then the conductive layer and the adhesive undercoat in the regions exposed by laser evaporation are removed by selective chemical etching. The protective layer is removed from the regions that are not exposed by laser evaporation and the vias, then the metal mask layer is removed. Finally, a protective barrier layer and a layer that provides solderability and/or weldability of the surface are applied.

### CROSS-REFERENCE TO RELATED APPLICATIONS

See Application Data Sheet.

### STATEMENT REGARDING FEDERALLY SPONSORED RESEARCH OR DEVELOPMENT

Not applicable.

### THE NAMES OF PARTIES TO A JOINT RESEARCH AGREEMENT

Not applicable.

### INCORPORATION-BY-REFERENCE OF MATERIAL SUBMITTED ON A COMPACT DISC OR AS A TEXT FILE VIA THE OFFICE ELECTRONIC FILING SYSTEM (EFS-WEB)

Not applicable.

### STATEMENT REGARDING PRIOR DISCLOSURES BY THE INVENTOR OR A JOINT INVENTOR

Not applicable.

### BACKGROUND OF THE INVENTION

1. Field of the Invention

The invention relates to methods for manufacturing printed circuit boards and may be used in electronic engineering and microelectronics for producing printed circuit boards for electronic circuits and semiconductor devices.

2. Description of Related Art Including Information Disclosed Under 37 CFR 1.97 and 37 CFR 1.98

A conventional multi-layer printed circuit board comprises a pack of dielectric substrates with conductive traces on their surfaces, which represent commutation layers, contact nodes in the form of metalized contacts aligned with each other and electrically and mechanically connected by a conductive material, said contact nodes being made as joints between the contacts. Each dielectric substrate with double-sided switching is characterized by that conductive traces are located at its both sides and are electrically connected therebetween by metalized vias. A key aspect is production of metalized vias and coupling them electrically with connection traces.

Various methods for manufacturing multi-layer printed circuit boards, wherein vias are produced by a drilling method (mechanical, laser, chemical etching), and metallization is carried out by activating surfaces of said vias and subsequent deposition of a conductive layer.

A method for applying a copper coating onto non-conductive surfaces of vias in a double-sided foil-clad printed circuit board by catalytic activation of the holes surfaces with a solution comprising Pd and Sn and subsequent electro-chemical copper deposition is known in the art (U.S. Pat. No. 4,671,968, 1987).

Also, a method for conditioning surfaces of non-foiled dielectric substrates with a Pd—Sn catalyst is known in the art (EP Patent No. 0328944, 1989). In respect of foil-clad substrates, a method for treating surfaces with cerium (IV) compounds after preliminary stripping of pressed-on copper foil is known in the art (U.S. Pat. No. 4,781,788, 1988).

Drawbacks of these methods comprising surface activation, in spite of their technological simplicity, are their high cost due to the use of activators produced from precious metals as well as insufficiently high adhesion of chemically deposited copper layers to the surface of a polymer array.

A method for producing a multi-layer printed circuit board is known, wherein conductors and metalized holes are formed by techniques of lithography and metallization deposition with subsequent building-up to a required thickness and conditioning of those locations where soldered connections will be made. Layers are assembled into a multi-layer structure by vacuum-soldering junctions between metalized vias (see, Panov, Ye. N., “Design features of assembling application-specific large-scale ICs on basic array crystals” (in Russian), M.: Vyshaya Shkola Publishers, p. 31-34, 1990). However, a drawback of this method is a complex multi-stage process requiring a big volume of precision and expensive equipment. Moreover, the use of galvanic building-up leads to shortcomings in metallization pattern, i.e., a conductive layer material is loose and of inferior quality in comparison with a voluminous one; the surface is rougher; undercuts are present; etc.

The closest to the proposed technical solution is a method for producing relief printed circuit boards (see, RU Patent No. 2416894 C1, 20.04.2011), comprising: generation of a relief pattern in the form of grooves and vias; formation of a conductive coating on the inner surfaces of said vias and grooves; before drilling of vias and generation of electric circuit pattern, the surface of a woven-glass reinforced substrate is first provided with a polymer protective coating, for which a lacquer or a glued film is used, then through holes are drilled, and the electric circuit relief is formed by milling or by using a laser beam; after that, a 3-4 micron Cu or Ni, or Mo, or Co conductive coating is deposited on the whole surface of the woven-glass reinforced substrate, including the inner surfaces of through holes and grooves of the electric circuit, and a protective film mask is applied thereon; then, the protective mask is removed from the relief surface of the electric circuit and the through holes by photolithography or laser beam; and the exposed regions of the thin conductive coating are galvanically provided with, first, a copper conductive coating and, second, a Sn—Pb, or Sn—Bi, or Rose's alloy resistive coating. Then, after removal of the remaining protective mask, the conductive coating is etched.

This method has a number of drawbacks:

1) The method is a complex and multi-stage one, since it comprises both application of thin metal layers and subsequent galvanic “building-up” of the conductive layer thickness to a value required for good conductance.

2) The conductive layer is a galvanically built-up layer. Layers, which are produced by galvanic building-up, have a loose, as compared to a voluminous material (e.g., copper), structure, and, due to this fact, conduction properties of a galvanic layer are less than those of a voluminous, or even deposited, e.g. by magnetron deposition, material.

3) At the final stage of this method, when a thin conductive coating is etched, undercutting of the basis of conductive traces occurs, and a cross-section of a conductive trace produced by this technology always looks as that shown in FIG. 1a. Apart from this defect, internal metallization layers of such a trace on the undercut side remain exposed, and such a spot is a place susceptible to future oxidation and corrosion.

4) Moreover, the surface of a layer built-up galvanically has greater roughness (FIG. 1a).

### BRIEF SUMMARY OF THE INVENTION

The objective of the claimed invention is to develop an efficient method for manufacturing double-sided printed circuit boards having high-quality conductive layers.

The technical effect of the invention is improved quality of a metallization pattern and improved switching reliability between the PCB sides, improved electric parameters of the conductive layer and higher efficiency of the method.

This technical effect of the claimed invention is achieved by the claimed method for manufacturing double-sided printed circuit boards owing to the following:
vias (through holes) are made in a non-conductive substrate according to given coordinates of the PCB layout,
an adhesion sub-layer, a conductive layer and a metal mask layer are deposited onto the surface of the substrate on both surfaces and onto the walls of the vias,
a soluble protective layer, which is stable towards chemical etchants, is applied onto the mask layer on both substrate surfaces and onto the walls of the vias,
a pattern is formed by laser evaporation of at least the protective layer and the mask layer in the regions not occupied by conductive traces,
the conductive layer and the adhesion sub-layer are removed by selective chemical etching in the regions exposed by laser evaporation,
the protective layer is removed from the surface of conductive traces and into the vias by using a solvent,
the metal mask layer is removed from the surface of conductive traces and into the vias by selective chemical etching,
the protective barrier layer and a solderability- and/or weldability-enabling layer is applied onto the conductive traces and into the vias on both sides of the substrate.

Moreover, the above technical effect is achieved in particular embodiments of the invention owing to the following:
a substrate of aluminum nitride or oxide is used as the substrate for the double-sided printed circuit board,
vias are made by laser drilling,
a chromium layer is applied as the adhesion sub-layer,
a copper layer is applied as the conductive layer,
a vanadium layer and a titanium layer are applied as the metal mask layer,
the adhesion sub-layer, the conductive layer and the metal mask layer are applied by magnetron deposition technique in the single technological process,
a wax layer is applied as the soluble protective layer by aerosol spraying, the protective layer being removed by using an organic solvent,
a nickel layer is applied as the barrier layer,
a gold or silver layer is applied as the solderability- and/or weldability-enabling layer.

The proposed method have certain advantages over the closest analog, namely:

1) The technological process is much shorter, the stage of galvanic building-up of the conductive layer is excluded. The conductive layer is applied in the single process.

2) The conductive layer quality and switching between the printed circuit board are improved. The vacuum-deposited conductive layer has better electric parameters than a layer produced by a galvanic-chemical technique.

### BRIEF DESCRIPTION OF THE SEVERAL VIEWS OF THE DRAWINGS

The claimed method is illustrated by the drawings.

FIG. 1a shows perspective views of layouts of conductive PCB traces made according to a method for galvanic building-up and subsequent etching-out of the thin layer.

FIG. 1b shows a perspective view of a layout of conductive PCT traces according to the proposed method.

FIG. 2 (a-g) are schematic views showing the main steps of the proposed method for manufacturing of a double-sided printed circuit board:

FIG. 2a: provision of the initial substrate,

FIG. 2b: making of vias (through holes),

FIG. 2 c: deposition of metal layers,

FIG. 2d: application of a protective layer,

FIG. 2e: laser explosion of the pattern,

FIG. 2f: chemical etching of the conductive and adhesion layers,

FIG. 2g: removal of the protective layer,

FIG. 2h: removal of the metal mask,

FIG. 2i: application of a barrier layer and a conductive trace soldability- and/or weldability-enabling layer.

FIG. 3a shows a perspective view of the area near a via of the printed circuit board after it is made without application of a protective layer.

FIG. 3b shows a perspective view of the area near a via of the printed circuit board after it is made and with application of a protective layer, according to the claimed method.

### DETAILED DESCRIPTION OF THE INVENTION

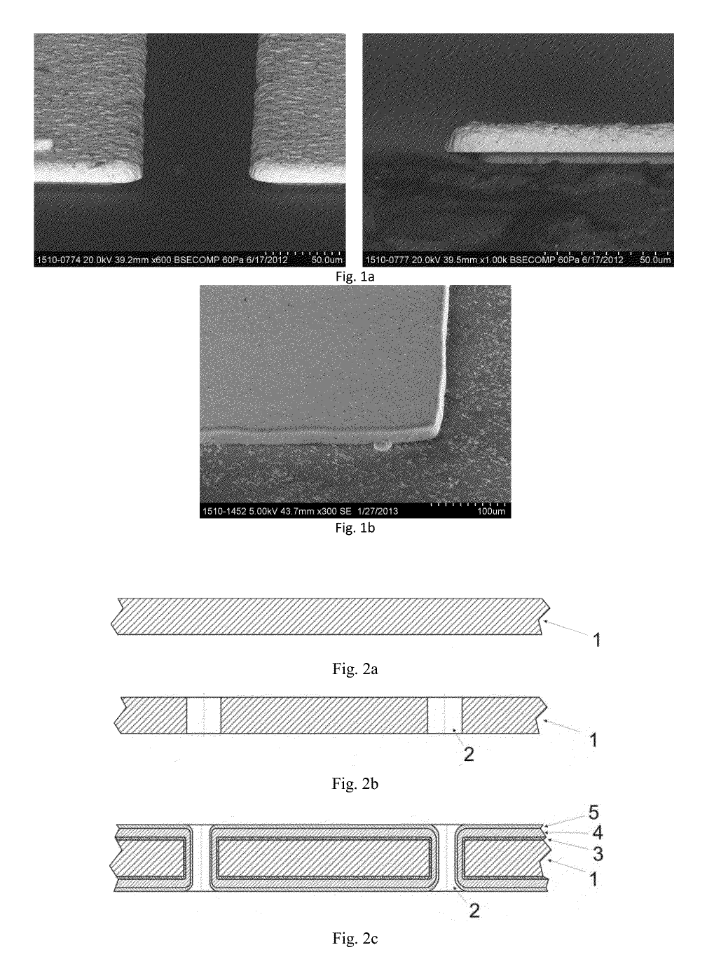

FIG. 1 The claimed method comprises the following steps:

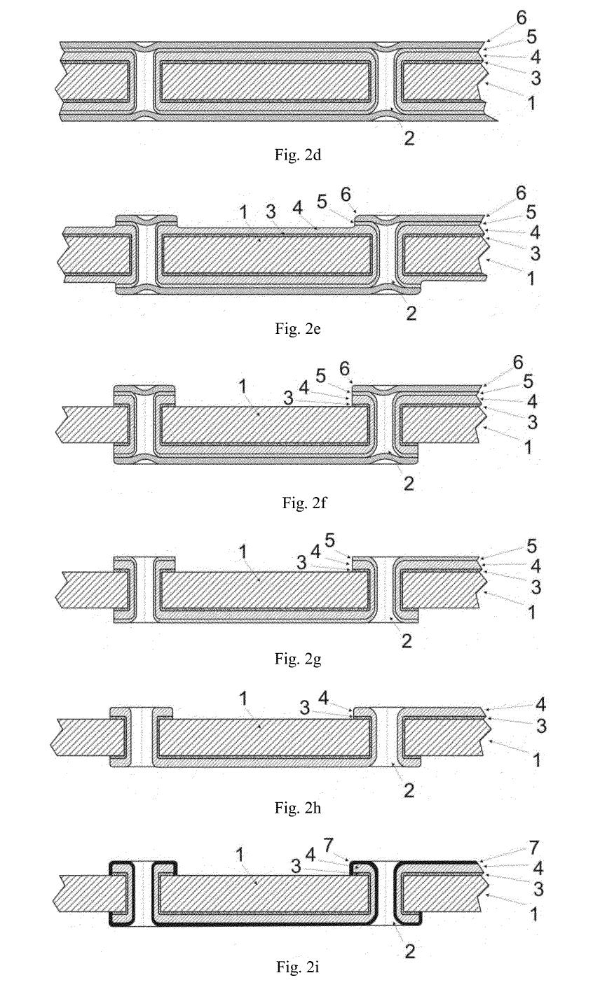

1) Vias (through holes) 2 are made, e.g., by a laser drilling technique (FIG. 2b), in the non-conductive substrate 1 (FIG. 2a) before deposition of conductive layers in the places having given coordinates defining the configuration of the printed circuit board.

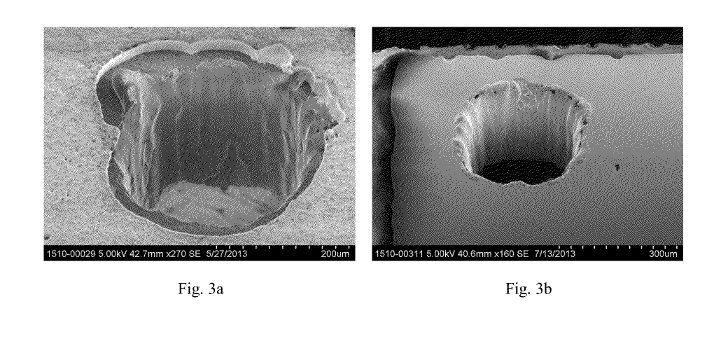

2) A solid conductive coating is deposited (e.g., by using a magnetron) on the two sides of the substrate 1. The coating consists of the adhesion sub-layer 3, the conductive layer 4 and the metal mask layer 5 (FIG. 3c). At this step this multi-layer coating also settles on the walls of the vias 2, which enables electric contact between the layers on both sides of the substrate 1. A chromium layer may be deposited as the adhesion sub-layer 3, and a copper layer may be deposited as the conductive layer 4. The mask layer 5 may be made of vanadium or may consist of two layers—a vanadium layer and a titanium layer.

3) The metalized surface (the mask layer 5) is provided with the protective layer 6 (FIG. 2d), which is readily dissolves in corresponding solvents, but is chemically stable at the subsequent stages of chemical treatment with acid etchants. A wax layer may be applied as the protective layer 6. The protective layer is used to prevent metallization in the vias from etching out during the subsequent etching operations.

4) A PCB pattern (see FIG. 2e) is formed on the surface of the produced multi-layer system. For this, the regions, which are not occupied by conductive traces of the future printed circuit board, are exposed by using laser evaporation of the protective layer 6 and the mask layer 5. Also, during this treatment the conductive layer 4 may be partially evaporated. This laser treatment is carried out on both sides of the substrate 1.

5) The substrate 1 with the exposed pattern is selectively etched by chemical etchants which remove the conductive layer 4 and the adhesion sub-layer 3 on the regions exposed by laser evaporation (i.e., the regions that are not occupied by the conductive traces) (see FIG. 2f). On the other regions of the substrate (including the vias), the protective layer 6 and the metal mask layer protect the PCB layers against chemical etching.

6) The protective layer 6 on the substrate regions that are not exposed by laser evaporation (i.e., on the conductive traces) and in the vias 2 is removed by using an organic solvent (FIG. 2g).

7) After that, the mask layer 5 is removed from the conductive traces and the vias by using a selective etchant that does not interact with the conductive layer 4 and the adhesion sub-layer 3 (FIG. 2h).

8) A barrier layer, e.g., a nickel layer, and a solderability- and/or weldability-enabling layer is deposited onto the produced surface in the regions that are not exposed by laser evaporation (the conductive traces) (see, FIG. 2i where both layers are indicated as 7). A layer of immersion gold or tin may be deposited as the solderability- and/or weldability-enabling layer.

In the result, a double-sided printed circuit board with switched conductive layers is formed.

### EXAMPLES OF SPECIFIC EMBODIMENTS OF THE CLAIMED METHOD

### Example 1

A series of vias are produced by laser drilling according to PCB given coordinates in a polished (Ra<0.1) ceramic substrate made of aluminum oxide. The characteristics of laser radiation and produced vias are indicated in Table 1.

TABLE 1
Characteristics of laser radiation and vias made thereby

| | | | Pulse | | |
|---|---|---|---|---|---|
| | Radiation | Pulse | repetition | Average | |
| Laser type | wavelength | duration | rate | power | Via size |
| Fiber laser | 1.064 microns | 1 μs | 100 Hz | 100 W | 0.25 mm |

Then the multi-layer metal coating, which consists of the adhesion coating, the conductive layer, and the mask layer, is magnetron-deposited onto the substrate with the vias produced. The characteristics of the deposited layers are given in Table 2. Deposition of the multi-layer coating in a single process is performed in a magnetron unit having a corresponding set of magnetron targets (Cr, Cu, V).

Magnetron deposition is carried out on both sides of the substrate and in the vias.

TABLE 2
Composition and parameters of the metallization layers deposited
in a single process (magnetron deposition) and their purpose

| Layer number from | Layer | | |
|---|---|---|---|
| the surface | composition | Thickness | Purpose |
| 1 | Vanadium (V) | 1 micron | Mask layer |
| 2 | Copper (Cu) | 20 microns | Conductive layer |
| 3 | Chromium (Cr) | 0.05 microns | Adhesion sub-layer |

Then, a thin layer of protective wax coating is applied from an aerosol can onto both sides of the substrate with the deposited layers. For example, the LIQUI MOLI™ Motor-Versiegelung aerosol wax coating may be used.

Then, the protective wax layer and the vanadium mask layer are selectively evaporated according to a preset program in a pulse laser unit designed for engraving a pattern by a scanning laser beam. The conductive trace regions are left non-evaporated. The laser radiation parameters are shown in Table 3.

TABLE 3
Parameters of laser radiation used for removing the mask layer

| | | | | | Beam |
|---|---|---|---|---|---|
| | | | Pulse | | scanning |
| | Radiation | Pulse | repetition | Average | speed on the |
| Laser type | wavelength | duration | rate | power | surface |
| Fiber laser | 1.064 microns | 1 ns | 100 KHz | 8 W | 100 mm/s |

Then, the copper conductive layer is removed to the chromium adhesion sub-layer in the first selective etchant (the etchant composition and the etching conditions are shown in Table 4). The selective etchant does not dissolve the vanadium mask layer and the chromium sub-layer.

After that, the protective wax coating is removed by using Solvent No. 646.

Then, the chromium adhesion sub-layer is etched in the second selective etchant (the etchant composition and the etching conditions are shown in Table 4), the vanadium pattern and copper being not etched.

Then, the vanadium mask layer is removed in the third selective etchant (the etchant composition and the etching conditions are shown in Table 4). The etchant does not interact with copper of the conductive trace pattern and with the chromium sub-layer.

TABLE 4
Parameters of the selective etchants and the etching modes used for generation of a
metallization pattern for contact traces

| | | Etchant | | Additional |
|---|---|---|---|---|
| Etchant number | Purpose | composition | Etching duration | conditions |
| 1 | Etching of copper | CrO₃ - 150 g/L | 5 minutes | Intensive stirring |
| | conductive layer | HNO₃ - 5 mL/L | | Room temperature |
| | | HCl - 10 mL/L | | |
| 2 | Etching of | HCl:H₂ O = 1:1 | 5 minutes | Room temperature |
| | chromium adhesion | | | |
| | sub-layer | | | |
| 3 | Etching of | H₂O₂ conc. | 2 minutes | Room temperature |
| | vanadium mask | | | |
| | layer | | | |

After the above steps, the surface has a pattern of conductive traces consisting of the chromium sub-layer and the main, copper conductive layer. Metallization is also present in the vias, ensuring contact between the conductive pattern on both sides of the substrate.

Then, a barrier layer is chemically deposited onto the surface of the conductive traces and the vias, and then a solderability- and weldability-enabling gold layer is also chemically deposited.

### Example 2

A series of vias are produced by laser drilling according to PCB given coordinates in a grinded (Rₐ<0.6) ceramic substrate made of aluminum nitride. The characteristics of laser radiation and produced vias are indicated in Table 5.

TABLE 5
Characteristics of laser radiation and vias produced thereby

| | | | Pulse | | |
|---|---|---|---|---|---|
| | Radiation | Pulse | repetition | Average | |
| Laser type | wavelength | duration | rate | power | Via size |
| Fiber laser | 1.064 microns | 10 μs | 100 Hz | 100 W | 0.25 mm |

Then, this substrate is provided with a multi-layer metal coating by magnetron deposition in a single process, the coating consisting of the layers which characteristics are shown in Table 6.

TABLE 6
Composition and parameters of the metallization layers deposited
in a single process (magnetron deposition) and their purpose

| Layer number from | Layer | | |
|---|---|---|---|
| the surface | composition | Thickness | Purpose |
| 1 | Titanium (Ti) | 1 micron | Mask layer |
| 2 | Vanadium (V) | 1 micron | (two-layer mask) |
| 3 | Copper (Cu) | 20 microns | Conductive layer |
| 4 | Chromium (Cr) | 0.05 microns | Adhesion sub-layer |

Magnetron deposition is carried out on the substrate two sides and in the vias. In this process, the deposited mask layer consists of two layers (those of vanadium and titanium), which is required due to developed rough surface of the substrate. Due to this, the mask surface will also have higher roughness, and more complex structure of the layer is required contrary to the above case where the substrate has polished surface.

The multi-layer coating is applied in a single process, i.e., in a single technological cycle, which can be carried out in a magnetron unit having a corresponding set of magnetron targets (Cr, Cu, V, Ti).

Then, a thin layer of protective wax coating is applied from an aerosol can onto both sides of the substrate with the deposited layers. For example, the LIQUI MOLI Motor-Versiegelung aerosol wax coating may be used.

Then, the protective wax layer and the mask layer comprising two sub-layers (vanadium and titanium) are selectively evaporated according to a preset program in a pulse laser unit designed for engraving a pattern by a scanning laser beam. The conductive trace regions are left non-evaporated. The laser radiation parameters are shown in Table 7.

TABLE 7
Parameters of laser radiation used for removing the mask layer

| | | | | | Beam |
|---|---|---|---|---|---|
| | | | Pulse | | scanning |
| | Radiation | Pulse | repetition | Average | speed on the |
| Laser type | wavelength | duration | rate | power | surface |
| Fiber laser | 1.064 microns | 100 ns | 20 KHz | 8 W | 100 mm/s |

Then, the copper conductive layer is removed to the chromium adhesion sub-layer in the first selective etchant (the etchant composition and the etching conditions are shown in Table 8). The selective etchant does not dissolve the vanadium/titanium mask layer and the chromium sub-layer.

After that, the protective wax coating is removed by using Solvent No. 646.

Then, the chromium adhesion sub-layer is etched in the second selective etchant (the etchant composition and the etching conditions are shown in Table 8), the vanadium pattern and copper being not etched.

Then, the vanadium/titanium mask layer is removed in the third and the fourth selective etchants (the etchant compositions and the etching conditions are shown in Table 8). The etchants do not interact with copper of the conductive trace pattern and with the chromium sub-layer.

TABLE 8
Parameters of the selective etchants and the etching modes used for generation of a
metallization pattern for contact traces

| | | | | |
|---|---|---|---|---|
| | | Etchant | | Additional |
| Etchant number | Purpose | composition | Etching duration | conditions |

| | | | | | |
|---|---|---|---|---|---|
| 1 | Etching of copper | CrO₃ - 150 g/L | 5 | minutes | Intensive stirring |
| | conductive layer | HNO₃ - 5 mL/L | | | Room temperature |
| | | HCl - 10 mL/L | | | |
| 2 | Etching of | HCl:H₂O = 1:1 | 5 | minutes | Room temperature |
| | chromium adhesion | | | | |
| | sub-layer | | | | |
| 3 | Etching of mask | H₂O₂ conc. | 2 | minutes | Room temperature |
| | layer - vanadium | | | | |
| 4 | Etching of mask | KOH_{4%}:HF_{conc.} = | 10 | seconds | Room temperature |
| | layer - titanium | 10:2 | | | |

After the above steps, the surface has a pattern of conductive traces consisting of the chromium sub-layer and the copper conductive layer. Metallization is also present in the vias, ensuring contact between the conductive pattern on both sides of the substrate.

Then, a barrier nickel layer is chemically deposited onto the surface of the conductive traces and the vias, and then a solderability- and weldability-enabling gold layer is also chemically deposited.

The claimed method is characterized by the following specific features:
Production of vias and application of metal layers enabling electric contact between the substrate sides to their lateral walls in a single deposition cycle, which is necessary for generation of a pattern of a full printed circuit board.
Application of a protective layer after deposition of metal layers. The application of a thin protective layer is necessary for protecting a metal coating deposited on the lateral walls of the vias. In the absence of such protection, when subsequent etching of a conductive layer and an adhesion sub-layer is carried out, the metal layers on the lateral walls of the vias may be etched out, since the metal mask layer on the lateral walls of the vias is very thin and cannot protect against etchants' action. FIG. 3 shows a comparison between an area of a commutation pattern without a protective layer (a) and with a protective layer (b) according to the claimed method. If no protective layer is used, chemical etching removes a metal mask layer in a via, and, as a result, commutation between the sides of a printed circuit board is violated, and the role of a via is canceled.
Removal of a protective layer, after it has fulfilled its function of protection against parasitic etching of metal layers in vias. A protective layer is removed prior to the step of metal mask removal, which also occurs in a single cycle for the whole printed circuit board, including vias, as the final application of a barrier layer and a layer for enabling solderability and/or weldability that are applied in a single cycle onto vias also.

Thus, the claimed method ensures creation of reliable communication between layers of a conductive pattern on different sides of a substrate.

1. A method for manufacturing a double-sided printed circuit board, said method comprising the steps of:
assembling via through-holes according to given coordinates of a PCB layout in a non-conductive substrate;
depositing an adhesion sub-layer, a conductive layer and a metal mask layer onto the substrate on two sides of the substrate and on walls of said via through-holes;
applying a soluble protective layer, said soluble protective layer being stable toward chemical etchants, onto the mask layer on the substrate;
forming a PCB pattern by laser evaporation of at least the protective layer and the mask layer in regions that are not occupied by conductive traces;
removing the conductive layer and the adhesion sub-layer in regions not occupied by conductive traces by selective chemical etching;
removing the protective layer from conductive traces and in said via through-holes by using a solvent;
removing the metal mask layer from conductive traces and in said via through-holes by selective chemical etching; and
applying a protective barrier layer and a layer enabling solderability and/or weldability of the surface onto conductive traces and said via through-holes on the two sides of the substrate.

2. The method according to claim 1, wherein the substrate is comprised of one of group consisting of: aluminum nitride and aluminum oxide.

3. The method according to claim 1, further comprising: forming said via through-holes by laser drilling.

4. The method according to claim 1, wherein said adhesion sub-layer is comprised of a chromium.

5. The method according to claim 1, wherein the said conductive layer is comprised of copper.

6. The method according to claim 1, wherein the metal mask layer is comprised of vanadium.

7. The method according to claim 1, wherein the metal mask layer is comprised of a vanadium layer and a titanium layer.

8. The method according to claim 1, wherein the step of applying the adhesion sub-layer, the conductive layer and the metal mask layer comprises the step of: applying magnetron deposition in a single technological process.

9. The method according to claim 1, wherein the step of applying said soluble protective layer comprises aerosol spraying so as to form a wax layer as said soluble protective layer, wherein said solvent in the step of removing the protective layer is comprised of an organic solvent.

10. The method according to claim 1, wherein said protective barrier layer is comprised of a nickel layer.

11. The method according to claim 1, wherein said layer enabling solderability and/or weldability is comprised of one of a group consisting of a gold layer and a tin layer.
